(19) United States
(12) Patent Application Publication
(10) Pub. No.: US 2007/0042556 A1
(43) Pub. Date: Feb. 22, 2007

(54) METHOD OF FABRICATING METAL OXIDE SEMICONDUCTOR TRANSISTOR

(76) Inventor: Chao-Sheng Lin, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/161,788

(22) Filed: Aug. 17, 2005

(51) Int. Cl. H01L 21/336

(52) U.S. Cl. 438/299

(57) ABSTRACT

A method of fabricating a metal oxide semiconductor transistor is described. A substrate having device isolation structures thereon is provided. A stack gate structure is formed over the substrate. An etching stop layer is formed over the substrate to cover the stack gate structure, the substrate and the device isolation structures. Thereafter, spacers are formed on the sidewalls of the stack gate structure. The spacers and the etching stop layer have different etching selectivity. A source region and a drain region are formed in the substrate beside the spacer on each side of the stack gate structure using the stack gate structure and the spacers as a mask. Then, the spacers are removed and a lightly doped region and a lightly doped drain region are formed in the substrate on each side of the stack gate structure using the stack gate structure as a mask.

### BACKGROUND OF THE INVENTION

1. Field of the Invention

The present invention relates to a method of manufacturing a semiconductor device. More particularly, the present invention relates to a method of fabricating a metal oxide semiconductor (MOS) transistor.

2. Description of the Related Art

Metal oxide semiconductor (MOS) transistor is currently one of the most popular single electronic devices in integrated circuit applications. With the rapid development of the semiconductor industry, precision and highly sophisticated integrated circuits are in great demand. As a result of the increase in the level of integration, the line width of devices is reduced correspondingly. As the dimension of a MOS transistor is reduced, its channel length will also decrease with ease leading to hot electron effect problem. At present, the most common method of reducing hot electron effect is to form a doped region having a doping concentration less than the source region and the drain region in the substrate of the MOS transistor close to the ends of the channel region.

FIGS. 1A and 1B are schematic cross-sectional views showing the steps for forming a conventional metal oxide semiconductor (MOS) transistor. As shown in FIG. 1A, a substrate 100 having a plurality of device isolation structures 101 thereon is provided. A stack gate structure 107 is formed over the substrate 100. The device isolation structures 101 are fabricated using silicon oxide. The stack gate structure 107 comprises a gate dielectric layer 103 and a gate layer 105. Thereafter, silicon oxide spacers 108 are formed on the sidewalls of the stack gate structure 107. Thereafter, using the stack gate structure 107 and the spacers 108 as a mask, an ion implantation is carried out to form a source region 110a and a drain region 111b in the substrate 100 beside the spacers 109.

As shown in FIG. 1b, the spacers 109 are removed. Using the stack gate structure 107 as a mask, another ion implantation is carried out to form a lightly doped source region 113a and a lightly doped drain 113b in the substrate 100 beside on the respective side of the stack gate 108.

In the aforementioned process of fabricating a MOS transistor, the spacers and the device isolation structures are fabricated using an identical material. In other words, the etching selectivity between material constituting the spacer and the material constituting the device isolation structure is absent. Hence, in the process of removing the spacers, a part of the device isolation structure can also be removed with ease leading to some destruction of the device isolation structure. When the device isolation structure is defective, the probability of having a current leak or a short circuit in the fabricated device is significantly increased and the reliability is most likely compromised.

### SUMMARY OF THE INVENTION

Accordingly, at least one objective of the present invention is to provide a method of fabricating a metal oxide semiconductor (MOS) transistor that can protect a device isolation structure inside the MOS transistor against any damage during the processing operation and produce a highly reliable and stable device.

To achieve these and other advantages and in accordance with the purpose of the invention, as embodied and broadly described herein, the invention provides a method of fabricating a metal oxide semiconductor (MOS) transistor. First, a substrate is provided. The substrate has a plurality of device isolation structures for defining out an active region. A stack gate structure is formed on the active region of the substrate. An etching stop layer is formed over the substrate to cover the stack gate structures, the substrate and the device isolation structures. Thereafter, a plurality of first spacers is formed on the sidewalls of the stack gate structure. The first spacers and the etching stop layer have different etching selectivity. A source region and a drain region are formed in the substrate beside the spacer on each side of the stack gate structure using the stack gate structure and the first spacers as a mask. Then, the first spacers are removed and a lightly doped region and a lightly doped drain region are formed in the substrate on each side of the stack gate structure using the stack gate structure as a mask.

According to one preferred embodiment of the aforementioned method of fabricating a MOS transistor in the present invention, the stack gate structure comprises a lower gate dielectric layer and an upper gate layer.

According to one preferred embodiment of the aforementioned method of fabricating a MOS transistor in the present invention, the etching stop layer is fabricated using silicon nitride or silicon oxynitride material.

According to one preferred embodiment of the aforementioned method of fabricating a MOS transistor in the present invention, the first spacers are fabricated using silicon oxide material.

According to one preferred embodiment of the aforementioned method of fabricating a MOS transistor in the present invention, after removing the first spacers but before forming the lightly doped source region and the lightly doped drain region, further comprises etching the etching stop layer to form a plurality of first offset spacers.

According to one preferred embodiment of the aforementioned method of fabricating a MOS transistor in the present invention, after removing the first spacers but before forming the lightly doped source region and the lightly doped drain region, further comprises removing the etching stop layer. In addition, according to another preferred embodiment of the method of fabricating the MOS transistor in the present invention, after removing the etching stop layer but before forming the lightly doped source region and the lightly doped drain region, further comprises forming a plurality of second offset spacers on the sidewalls of the stack gate structure.

According to one preferred embodiment of the aforementioned method of fabricating a MOS transistor in the present invention, after forming the lightly doped source region and the lightly doped drain region, further comprises forming a plurality of second spacers on the sidewalls of the stack gate structure. Each second spacer comprises a lower silicon oxide layer and an upper silicon nitride layer. Furthermore, after forming the second spacers, further comprises forming a conductive layer on the source region and the drain region. The conductive layer is fabricated using salicide, for example.

According to one preferred embodiment of the aforementioned method of fabricating a MOS transistor in the present invention, after forming the source region and the drain region but before removing the first spacers, further comprises performing an anneal process.

According to one preferred embodiment of the aforementioned method of fabricating a MOS transistor in the present invention, after removing the first spacers but before forming the lightly doped source region and the lightly doped drain region, further comprises performing an anneal process.

In the present invention, an etching stop layer is formed over the substrate to cover the stack gate structure, the substrate and the device isolation structures before forming the spacers. Hence, the device isolation structure will not be removed along with the spacers in the process of removing the spacers because of low etching selectivity between the two. Thus, the device isolation structures are protected against processing damages and the probability of having a current leak or short-circuit is significantly reduced in the manufactured device. Ultimately, a highly reliable and stable product is produced.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A and 1B are schematic cross-sectional views showing the steps for forming a conventional metal oxide semiconductor (MOS) transistor.

FIGS. 2A through 2F are schematic cross-sectional views showing the steps for forming a metal oxide semiconductor (MOS) transistor according to one preferred embodiment of the present invention.

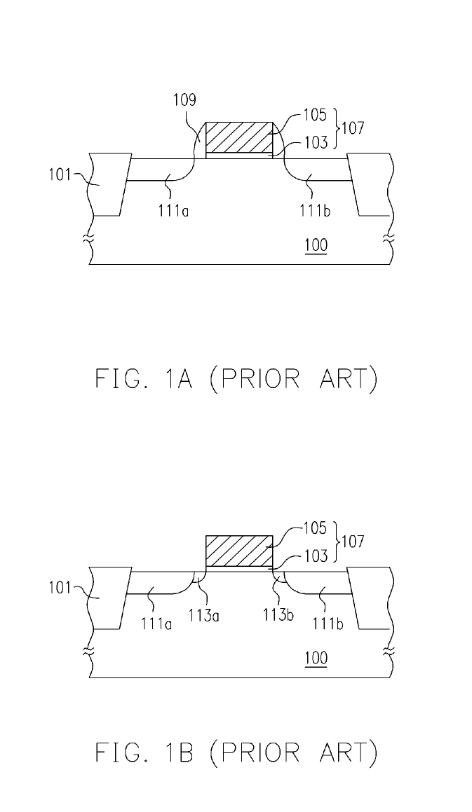

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

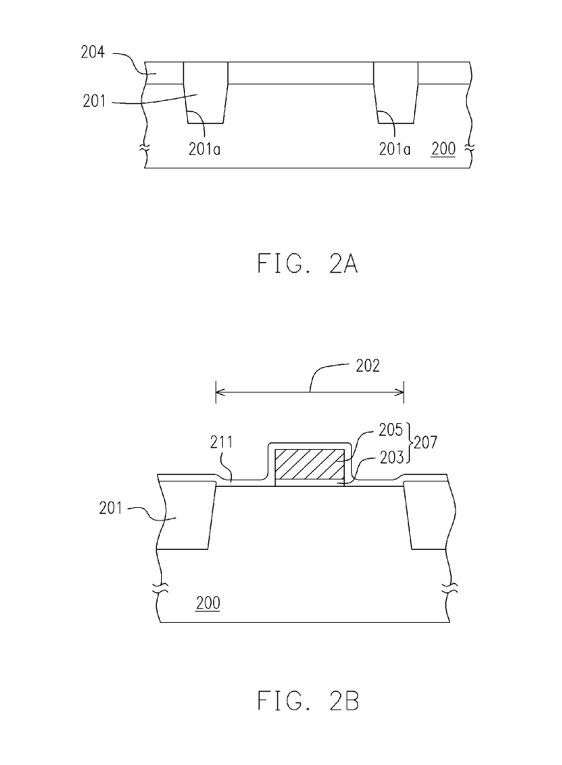

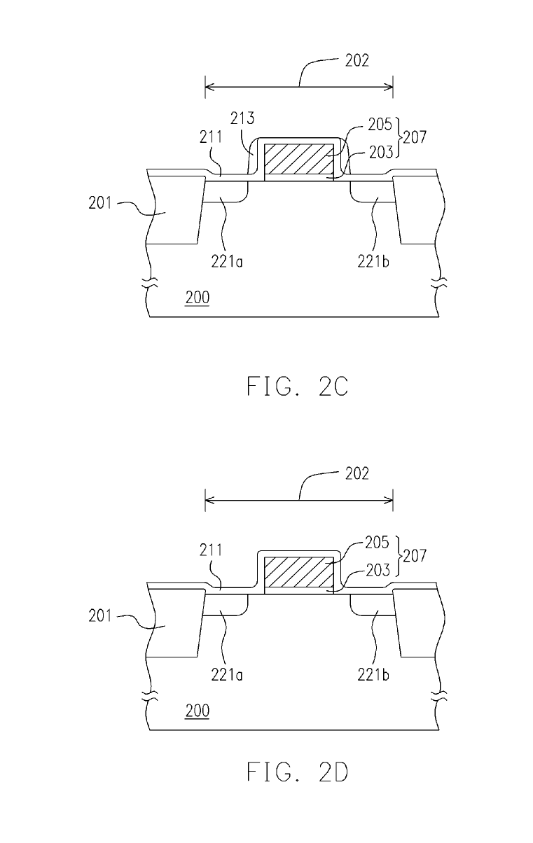

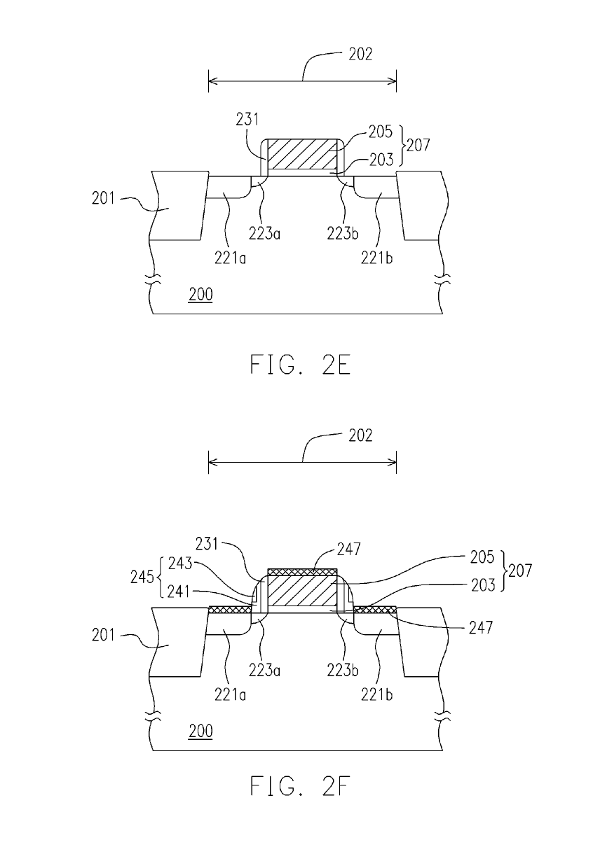

FIGS. 2A through 2F are schematic cross-sectional views showing the steps for forming a metal oxide semiconductor (MOS) transistor according to one preferred embodiment of the present invention. As shown in FIG. 2A, device isolation structures 201 are formed on the substrate 200. The method of forming the device isolation structures 201 includes, for example, forming a patterned hard mask layer 204 over the substrate 200. Thereafter, using the hard mask layer 204 as a mask, a trench 201 a is etched in the substrate 200 and then insulating material is deposited to fill the trench 201a. The insulating material can be silicon oxide, for example. After that, the insulating material outside the trench 201a is removed and then followed by the hard mask layer 204. Thus, the device isolation structure 201 that defines an active region 202 is formed as shown in FIG. 2B. Obviously, the aforementioned method of forming the device isolation structures 201 is the method of forming shallow trench isolation (STI) structures. In another embodiment, the device isolation structures 201 can be field oxide isolation structures formed, for example, by a thermal oxidation process.

Thereafter, a stack gate structure 207 is formed on the active region 202 of the substrate 200. In one embodiment, the stack gate structure 207 comprises a lower gate dielectric layer 203 and an upper gate layer 205. The method of forming the stack gate structure 207 includes depositing a dielectric material to form a gate material layer (not shown) such as a silicon oxide layer on the substrate 200 in a thermal oxidation process. Then, polysilicon material is deposited over the gate material layer to form a polysilicon layer. After that, a photolithographic process and an etching process are carried out to pattern out the gate dielectric layer 203 and the gate layer 205, thereby forming the stack gate structure 207. The aforementioned gate layer 205 is fabricated using polysilicon. However, in other embodiment, the gate layer 205 can be fabricated using other conductive material including, for example, metallic or metal silicide.

As shown in FIG. 2C, an etching stop layer 211 is formed over the substrate 200 to cover the stack gate structure 207, the substrate 200 and the device isolation structures 201. The etching stop layer 211 is a silicon nitride layer or a silicon oxynitride layer formed, for example, by performing a chemical vapor deposition (CVD) process.

Thereafter, a plurality of spacers 213 is formed on the sidewalls of the stack gate structure 207. Here, there is no particular limitation on the material forming the spacers 213 as long as it has an etching selectivity different from the etching stop layer 211. For example, if the material selected for forming the etching stop layer 211 is silicon nitride or silicon oxynitride, then the material constituting the spacers 213 can be silicon oxide. Furthermore, the method of forming the spacers 213 includes depositing spacer material to form a spacer material layer (not shown) in a chemical vapor deposition process and then performing an anisotropic etching. Hence, the spacers 213 covers a portion of the etching stop layer 211.

Using the stack gate structure 207 and the spacers 213 as a mask, a source region 221a and a drain region 221b are formed in the substrate beside the spacer 213 on each side of the stack gate structure 207. The source region 221a and the drain region 221b are formed in an ion implantation process, for example. In one embodiment, after forming the source region 221a and the drain region 221b, further includes performing an anneal process, and such as a high temperature anneal process.

As shown in FIG. 2D, the spacers 213 are removed. The method of removing the spacers 213 includes performing an etching operation. Since the spacers 213 and the etching stop layer 211 have different etching selectivity, the etching stop layer 211 can serve as a protective layer preventing any damage to the device isolation structures 201 in the process of removing the spacers 213.

In addition, in one preferred embodiment, after removing the spacers 213, further includes etching the etching stop layer 211 to form a plurality of offset spacers 231 as shown in FIG. 2E. The method of etching the etching stop layer 211 includes performing an anisotropic etching operation. Alternatively, in another preferred embodiment, further includes removing the etching stop layer 211 and then forming the offset spacers 231 on the sidewalls of the stack gate structure 207 as shown in FIG. 2E. The offset spacers 231 serves as a protective layer protecting the stack gate structure 207 against possible damages in subsequent processes.

Thereafter, using the stack gate structure 207 as a mask shown in FIG. 2E, a lightly doped source region 223a and a lightly doped drain region 223b are formed in the substrate 200 on each side of the stack gate structure 207. The lightly doped source region 223a and the lightly doped drain region 223b are formed in an ion implantation process, for example. In one embodiment, before forming the lightly doped source region 223a and the lightly doped drain region 223b, further includes performing an anneal process, and such as a high temperature anneal process.

In one preferred embodiment as shown in FIG. 2F, after forming the lightly doped source region 223a and the lightly doped drain region 223b, further includes forming a plurality of spacers 245. The spacers 245 can be a dielectric stack layer comprising a lower silicon oxide layer 241 and an upper silicon nitride layer 243. The method of forming the silicon oxide layer 241 and the silicon nitride layer 243 includes performing a chemical vapor deposition process, for example.

After forming the spacers 245, a conductive layer 247 is formed on the source region 221a, the drain region 221b and the gate layer 205 to reduce the resistance thereof. The conductive layer 247 is fabricated, for example, by salicide.

In summary, an etching stop layer is formed over the substrate to cover the stack gate structure, the substrate and the device isolation structures before forming the spacers. Hence, the device isolation structures will not be etched in the process of removing the spacers. Thus, the device isolation structures are protected against processing damages and the probability of having a current leak or short-circuit is significantly reduced in the manufactured device. Ultimately, a highly reliable and stable product is produced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a metal oxide semiconductor (MOS) transistor, comprising the steps of:
providing a substrate having device a plurality of isolation structures thereon for defining out an active region;
forming a stack gate structure on the active region of the substrate;
forming an etching stop layer over the substrate to cover the stack gate structure, the substrate and the device isolation structures;
forming a plurality of first spacers on the sidewalls of the stack gate structure, wherein the first spacers and the etching stop layer have different etching selectivity;
forming a source region and a drain region in the substrate beside the first spacer on each side of the stack gate structure using the stack gate structure and the spacers as a mask;
removing the first spacers; and
forming a lightly doped source region and a lightly doped drain region in the substrate on each side of the stack gate structure using the stack gate structure as a mask.

2. The method of claim 1, wherein the material constituting the etching stop layer comprises silicon nitride or silicon oxynitride.

3. The method of claim 1, wherein the material constituting the first spacers comprises silicon oxide.

4. The method of claim 1, wherein after removing the first spacers but before forming the lightly doped drain region and the lightly doped source region, further comprises etching the etching stop layer to form a plurality of first offset spacers.

5. The method of claim 1, wherein after removing the first spacers but before forming the lightly doped drain region and the lightly doped source region, further comprises removing the etching stop layer.

6. The method of claim 5, wherein after removing the etching stop layer but before forming the lightly doped source region and the lightly doped drain region, further comprises forming a plurality of second offset spacers on the sidewalls of the stack gate structure.

7. The method of claim 1, wherein after forming the lightly doped source region and the lightly doped drain region, further comprises forming a plurality of second spacers on the sidewalls of the stack gate structure.

8. The method of claim 7, wherein the second spacers comprise a lower silicon oxide layer and an upper silicon nitride layer.

9. The method of claim 7, wherein after forming the second spacers, further comprises forming a conductive layer on the drain region and the source region.

10. The method of claim 9, wherein the material constituting the conductive layer comprises salicide.

11. The method of claim 1, wherein the stack gate structure comprises a lower gate dielectric layer and an upper gate layer.

12. The method of claim 1, wherein after forming the source region and the drain region but before removing the first spacers, further comprises performing an anneal process.

13. The method of claim 1, wherein after removing the first spacers but before forming the lightly doped source region and the lightly doped drain region, further includes performing an anneal process.
